(19) United States
(12) Patent Application Publication
(10) Pub. No.: US 2014/0132481 A1
(43) Pub. Date: May 15, 2014

(54) MOBILE DEVICES WITH PLURAL DISPLAYS

(71) Applicant: MICROSOFT CORPORATION, Redmond, WA (US)

(72) Inventors: Cynthia Bell, Kirkland, WA (US); William Jefferson Westerinen, Preston, WA (US); Tao Liu, Redmond, WA (US)

(73) Assignee: MICROSOFT CORPORATION, Redmond, WA (US)

(21) Appl. No.: 13/738,249

(22) Filed: Jan. 10, 2013

Related U.S. Application Data
(60) Provisional application No. 61/724,712, filed on Nov. 9, 2012.

(51) Int. Cl. H05K 5/00

(52) U.S. Cl. CPC H05K 5/0017
USPC 345/1.3; 361/679.01

(57) ABSTRACT

Disclosed herein are embodiments of mobile devices having plural displays. In some embodiments a mobile computing device comprises a body comprising a front side, a rear side, and four lateral sides, a main display on the front side of the body, and a secondary display on one of the four lateral sides of the body. An edge of the secondary display can be adjacent to an edge of the main display and the adjacent edges can positioned in contact with each other, can be joined together with an adhesive, and/or can be joined together with a compliant gasket. The main display and the secondary display can be controlled independently of each other based on predetermined display preference logic. The device can further comprise a cover layer that covers and protects both the main display and the secondary display.

### CROSS-REFERENCE TO RELATED APPLICATION

This application claims the benefit of U.S. Provisional Application No. 61/724,712, filed Nov. 9, 2012, which is incorporated by reference herein.

### BACKGROUND

As reliance of information accessed through mobile computing devices (laptops, tablets, smart phones) has grown, the desire for information ‘snacking’ has increased. Snacking is the behavior where a user uses their mobile device frequently and for short durations to look at small pieces of information. Frequently snacked-upon information can include the time of day, stock tickers, sports scores, social media feeds, e-mail inbox status, calendar, text messages, incoming call information, etc.

### SUMMARY

Disclosed herein are embodiments of mobile computing devices having plural displays. In some embodiments, the mobile computing device comprises a non-hinged or bar-type body comprising a front side, a rear side, and four lateral sides extending between the front side and the rear side, with a main display on the front side and at least one secondary display the front side or one of the lateral sides. The main display and the secondary display can comprise two discrete electronic display devices, and in some embodiments can comprise touch-sensitive input devices as well as visual display devices. The main display and the secondary display can be turned on and off independently of each other, and otherwise independently controlled to display desired information based on preset display logic. For example, a smaller secondary display can be left on when a larger main display is off in order to display snacking information while conserving energy.

In some embodiments, the main display and the secondary display are coupled together along a common edge, such as with matching beveled edges, with an adhesive, and/or with a compliant gasket. The main display can be disposed in a plane that is non-parallel with a plane in which the secondary display is disposed, such as at right angles or obtuse angles. In some embodiments, the secondary display can be located on a lateral side of the device that is canted out at an obtuse angle to the front side such that the secondary device is visible from the front of the device.

The device can comprise a one-piece, at least partially transparent cover layer that covers both the main display and the secondary display. When the secondary display is disposed on a lateral side of the device, the cover layer can extend around the edge of the mobile device to cover both displays. In some embodiments the device can include at least a third display on another lateral side and the cover layer can extend around at least two edges of the device to cover all the displays. The portions of the cover layer that covers the secondary display can comprise a convex outer surface to magnify the information displayed there.

The mobile device can include at least one display controller configured to determine when the main display is on or off and when the secondary display is on or off, and what information is displayed when either screen is on, based on input data received from one or more sensors, a battery charge level, and/or characteristics of data received that is to be displayed. The device can use various factors to determine when to use the secondary display. These factors can include the orientation of the device, whether the main display is being used or is facing another surface, the battery charge level, the current function of the device (e.g., in a phone call, etc.), the type and size of the information to be displayed, etc.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. The foregoing and other objects, features, and advantages of the inventions will become more apparent from the following detailed description, which proceeds with reference to the accompanying figures.

### BRIEF DESCRIPTION OF THE DRAWINGS

FIG. 1 is a schematic diagram depicting an exemplary mobile device with which any of the disclosed embodiments can be implemented.

FIG. 2 is a schematic diagram illustrating a generalized example of a suitable implementation environment for any of the disclosed embodiments.

FIG. 3 is a schematic diagram illustrating a generalized example of a suitable computing environment for any of the disclosed embodiments.

FIG. 4A shows an exemplary mobile device having a main display and a secondary display on one side, with only the secondary display on.

FIG. 4B shows the exemplary mobile device of FIG. 4A with both displays on.

FIG. 5 shows another exemplary mobile device having main display and a secondary display on one end, with both displays on.

FIG. 6 is a cross-sectional view of a main display and an adjacent secondary display adjoined at right angles, with both displays covered by a cover layer.

FIG. 7 is a cross-sectional view of a main display and two adjacent secondary displays adjoined at obtuse angles, with the three displays covered by a cover layer.

FIG. 8 shows a main display and a coplanar secondary display.

FIG. 9 is a flow chart illustrating exemplary methods disclosed herein.

### DETAILED DESCRIPTION

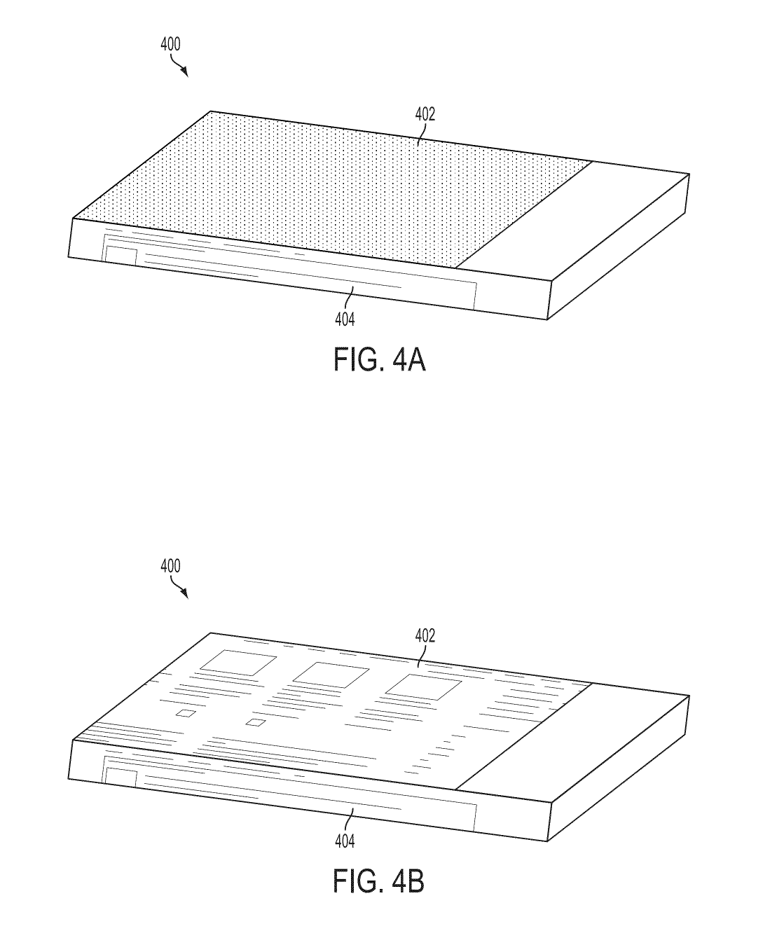

Described herein are embodiments of mobile computing devices that comprise plural displays. For example, FIGS. 4A and 4B show an embodiment of a mobile device 400 comprising a main display 402 on its front surface and a secondary display 404 on its side surface. In some conditions, the main display 402 can be off while the secondary display 404 is on, as shown in FIG. 4A. In other situations, both displays 402 and 404 can be on at the same time, as shown in FIG. 4B. In other situations, both displays 402 and 404 can be off. The plural displays can be turned on and off, and otherwise controlled, independently of one another.

The plural display technology described herein can be implemented on a mobile computing device comprising a body having a front side, a rear side, and four lateral sides. In some embodiments, the body can be generally cuboid. In some embodiments, the body can have a “bar” type form factor. In some embodiments, the device has a fixed, monolithic body with integrated displays that are stationary relative to one another so that it does not comprise two or more panels that slide, pivot, or otherwise move relative to one another during normal operation of the device. In some embodiments, the body can be non-hinged. In some embodiments, the body does not comprise a sliding mechanism. In other embodiments, the plural display technology described herein can be implemented on a mobile computing device plural body portions that are hinged, pivotable, slidable, or otherwise movable relative to each other, such as a hinged laptop, a slider phone, etc.

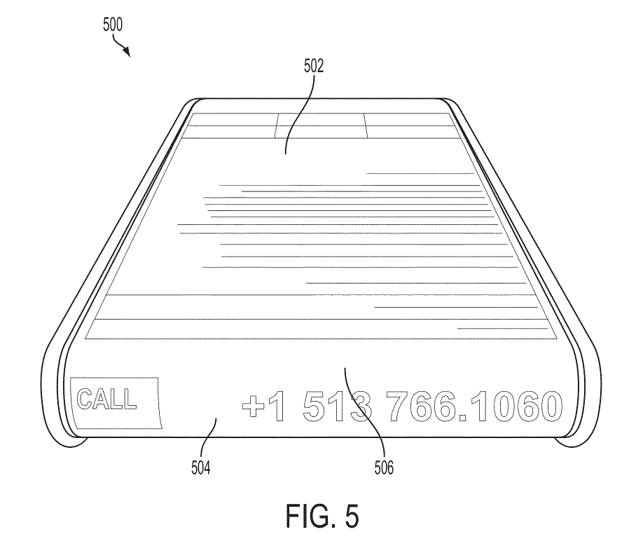

While the main display is located on the front side of a mobile device, one or more secondary displays, such as the secondary display 402, can be located on one or more lateral sides of the device, which includes the left and right sides and the top and bottom ends of the device, on the rear side of the device, and/or on the front side of the device. FIG. 5 shows another exemplary mobile device 500 that has a main display 502 on the front side and a secondary display 504 on a top end of the mobile device. Any number of secondary displays can be present on any combination of surfaces of a mobile device in alternative embodiments.

A secondary display can be smaller in area and consequently can use less power than the main display. For example, a smaller secondary display can be used to display small pieces of information while a larger main display is off, thereby saving power relative to leaving the larger main display on to display the same information. In some embodiments, the main display can be set to turn off automatically after a given period of inactivity to save energy and the secondary display can remain on for a longer period of time, or indefinitely, to display snacking information.

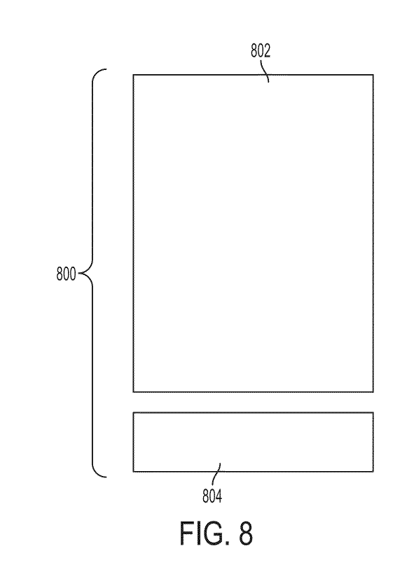

In some embodiments, a main display and a secondary display can comprise two portions of single display. For example, in FIG. 8, a display 800 of a mobile device can comprise a larger upper region 802 that functions as a main display and a smaller lower region 804 that functions as a secondary display. In some embodiments, the main display 802 can comprise a discrete display device separate from the secondary display device 804, with the two display devices being positioned in a coplanar arrangement, such as on the front side of a mobile device. The secondary display 804 can be positioned along any one or more edge of main display 802, including above, below, and/or to the side of the main display.

In some embodiments, a single display device, such as an organic LED based display device, can wrap around an edge of a mobile device to provide a main display region on one face of the mobile device, such as the front side, and a secondary display region on an adjacent lateral side of the mobile device. For example, the main display region can be at a 90° angle to the secondary display region. In such embodiments, the single display device can comprise a flexible material that allows the display to be bent sharply enough to wrap around an edge of the mobile device. In alternative embodiments, a single display device can be manufactured in a three dimensional shape having one or more integral bends or angles for wrapping around edges of a mobile device. A single display embodiment that extends around an edge of a mobile device can include a main display region on one face and a secondary display region on another face that can be selectively driven or operated. By using a single display to provide plural display regions on different faces, there can be no seem between the display regions at the edge of the mobile device. In some embodiments, the portion of the display that extends around an edge of a mobile device can be curved, as shown in FIG. 5, and in other embodiments the display can comprise a more angular ridge at the edge of the device.

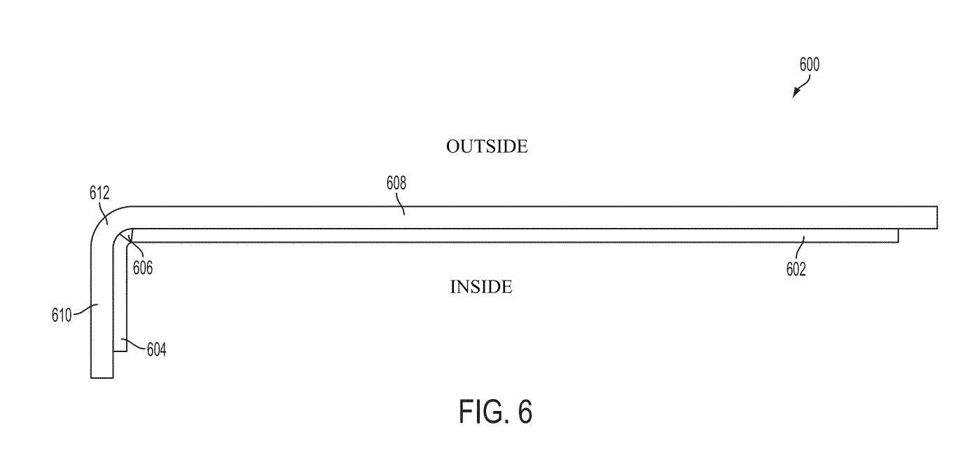

In some embodiments, the main display can comprise a separate display device from the secondary display device. The two displays can comprise two different LCD display devices. In other embodiments, one or more of the displays can comprise an electrophoretic display (EPD) or other bistable display. The secondary display can be positioned spaced apart from the main display, such as with a non-display structural member or other divider positioned between the two displays. In other embodiments, the main display and the secondary display can be coupled together along a common edge. The secondary display can be positioned with an edge adjacent an edge of the main display, such as in a non-planar or non-parallel, angled arrangement. FIG. 6 shows an exemplary configuration 600 wherein a main display 602 and a secondary display 604 are positioned adjacent to each other at a right angle. The main display 602 can be positioned on a front side of a mobile device while the secondary display 604 can be positioned on a lateral side of the mobile device.

In some embodiments, the adjacent edges of the two displays 602, 604 can be shaped to mate flushly with each other. For example, the two edges can each be beveled or chamfered at complimentary angles, such as 45° angles, such that they join or mate together at right angles to each other. In other embodiments, the two display edges can be beveled or chamfered to align at non-right angles. The displays 602, 604 can be formed on substrate materials, such as glass or polymeric materials, that can be shaped to provide a nearly seamless interface at the adjacent edges. Adhesion or other similar techniques can be used to bond the two display edges together. In some embodiments, the adjacent displays 602, 604 can comprise narrow bezel LCD displays.

The distance from the active display area of the displays to the physical edge of the displays can be as small as 0.2 mm, or smaller, such that the only a very small gap of non-displaying material is present between the two adjacent displays. This can give the appearance of a seamless transition around the edge of the mobile device such that an image can wrap around the edge between the two displays and appear as if it is being displayed on a singular display. In some embodiments, a secondary display can serve to extend the main display when it is on. For example, while scrolling horizontally through application icons, the icons can initially appear on a secondary display on one lateral side of a device and sweep around the edge onto the main display on the front side of the device. The icons can also sweep around the edge on the opposite side of the main display onto another secondary display on the opposite lateral side of the device. Similarly, stock tickers or other streams of information can scroll continuously around two or three sides of a device across plural displays.

In some embodiments, a strip of compliant material can join the adjacent edges of two displays. For example, in FIG. 6, the main display 602 can be coupled to the secondary display 604 with a compliant gasket 606. Such a gasket can be made of rubber or other resilient material. The thickness of the gasket 606 can vary. In some embodiments, a thicker gasket 606 can be used to accentuate the gap between the two displays, such as an opaque gasket that gives the appearance of a strong edge to the mobile device. In other embodiments, a thinner gasket 606 can be used to reduce the visible gap between the two adjacent displays. The gasket 606 can comprise an at least partially translucent or transparent material to further reduce its visibility. Using a gasket between the adjacent displays can provide a less expensive solution relative to forming beveled edges between the displays and/or bonding them directly together. In embodiments having a translucent or transparent gasket between the displays, an underlying backlight unit of one of the adjacent displays can be extended under the gasket to also couple light through the gasket. This can serve to make the gasket a colorful, luminous feature of the mobile device.

The displays 602, 604 can be covered by a seamless cover layer 608 that extends over both displays. The cover layer 608 can comprise a protective, at least partially translucent/transparent material, such as glass or polymeric material, that protects the underlying displays and the fragile joints between them without inhibiting the displayed information. As shown in FIG. 6, the cover layer 608 can comprise a right angled bend 612 between two planar portions 608 and 610 in embodiments where the main display 602 is at a right angle with the secondary display 604. The bend portion 612 of the cover lay can have varying degrees of roundness or angularity in different embodiments. The cover layer 608 can be referred to as a “3D” or three-dimensional cover layer to the bend 612 and angled side portion 610. In other embodiments, the cover layer can comprise a flat or planar configuration, such as in the example shown in FIG. 8 wherein the main display 802 and the secondary display 804 are coplanar.

In some embodiments, the cover layer can comprise a screen print or other dressing to make certain portions of the cover layer opaque or for other purposes. For example, the bend portion 612 of the cover layer 608 that covers the joint between adjacent displays can be made opaque to hide the joint and/or to give the impression of two discrete displays instead of one continuous display that wraps around the edge. In some embodiments, one or more perimeter edges of the cover layer can be made opaque to cover the perimeter edges of the displays, such as the edge portions of the displays that do not display anything and/or the joints between the edges of the displays on neighboring structural materials and circuitry of the device. In some embodiments, certain sensors can be covered by specially coated portions of the cover layer, such as to manage light reaching light sensors or to filter light reaching proximity sensors. The inside and/or outside surfaces of the cover layer can be coated. In some embodiments, the cover layer can be coated for cosmetic or aesthetic purposes. Exemplary cover layer coating processes can comprise screen printing, pad printing, etching, and other similar processes.

The cover layer 608 can be joined to the underlying displays 602, 604 and or the gasket 606 using UV curable adhesive or other adhesive material. For example, after coating the cover layer 608 as desired, an adhesive material can be applied to the inner surfaces of the cover layer and/or to outer surfaces of the displays. Next, the main display 602 can be attached to the inner surface of the cover layer 608, at its larger area can be most difficult to set free from air bubbles. Next, the gasket 606 can be attached to the cover layer 608 and/or to the side edge of the main display 602. In some embodiments, the gasket 606 can be adhered only at certain locations, such as at its longitudinal ends, to the cover layer and/or to the displays to provide a more exact interface with the adjacent edges of the displays. The gasket 606 can be adhered with UV curable adhesive, pressure sensitive adhesive, or other mechanism. Next, the secondary display 604 can be positioned against the gasket 606 and adhered to the inside surface of the side portion 610 of the cover layer. The adhesive can be cured with UV light or other mechanisms. In some embodiments, each of the displays can be cured in place one at a time before the next display is applied to the cover layer. In other embodiments, all of the adhesive can be cured at once after all the displays are set in place.

After the displays are coupled to the inner surfaces of the cover layer, a subframe supporting the displays and their backlight units, or light guides, can be added to the assembly. The subframe and light guides can be adhered to the perimeter of the cover layer in some embodiments, such as with pressure sensitive adhesive tape or other adhesive.

In some embodiments, the light guides can comprise a light distributor and a plurality of LEDs, such as white LEDs, that together serve to evenly illuminate the displays. In some embodiments, each of the main display and the secondary display can have their own respective light guides. In some embodiments, when the main display is off and the secondary display is on, the light guide for the main display can be turned off and the light guide for the secondary display can be left on. In some embodiments, the light guide for the secondary display can comprise as few as one or two LEDs, reducing the power consumption by the light guides compared to if the main light guide were to be left on.

In some embodiments, the cover layer 608 can comprise a convex outer surface to produce a magnification effect. For example, the side portion 610 of the cover layer can have a flat inner surface for bonding with the flat secondary display 604 and can have a convex outer surface that magnifies the information displayed on the secondary display 604. Similarly, the main portion of the cover layer 608 can also have a convex outer surface to magnify the information displayed by the main display 602. Magnification, especially on smaller secondary displays, can help the user read smaller type, such as while viewing a side-positioned secondary display from non-perpendicular angles. For example, a mobile device lying on a table having a secondary display on a side surface is likely to be viewed from an angle between perpendicular to the secondary display and parallel to the secondary display, such as at 45°. A non-perpendicular viewing angle can make the information appear even smaller, and magnification from a convex cover layer can help make the information more readable.

Some embodiments of mobile devices can comprise adjoining surfaces that are at non-right angles to one another. For example, some mobile devices can comprise side surfaces and/or end surfaces that are canted outwardly such that one of the front surface or the rear surface of the device is greater in area than the other. The side and/or end surfaces can extend at an obtuse or acute angle, instead of a traditional 90° angle, between parallel front and rear surfaces such that they can be visible by a user looking at the top surface of the device from a perpendicular viewing angle. In some such embodiments, when the device is lying on a table on its rear surface, the side and/or end panels can be more easily viewable, while in other embodiments, when the device is lying on a table on its front surface, the side and/or end panels can be more easily viewable.

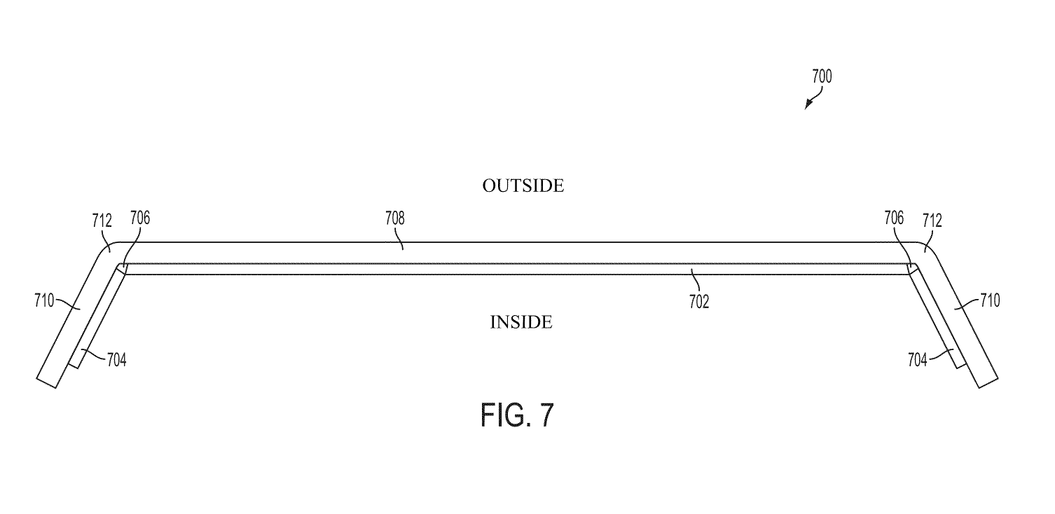

FIG. 7 shows an exemplary display configuration 700 comprising a main display 702 and two adjacent secondary displays 704 that extend from the main display at obtuse angles. For example, the main display 702 can span across the width of the front side of a mobile device and the two secondary displays 704 can extend along canted lateral side surfaces or end surfaces of the mobile device. The cover layer can extend around any number of edges of a mobile device.

The secondary displays 704 can be joined to the main display with adhesive or gaskets 706, as described above with respect to the configuration 600 and FIG. 6. In the configuration 700, due to the non-right angle joins between the displays, the gaskets 706 can comprise a more wedge shaped configuration. The gaskets can have a triangular or trapezoidal cross-sectional shape. The displays 702 and 704 can be covered by a cover layer 708 that comprise canted side portions 710 and obtuse bend portion 712. The cover layer 708 can be attached to the displays 702, 706 and/or gaskets 706 as described above with reference to the configuration 600 and FIG. 6.

In some embodiments, a secondary display can comprise a touchscreen or other touch-sensitive input function or other interactive features in addition to displaying information. For example, a secondary display can comprise virtual buttons or software controls that can be activated by touching them with a finger or stylus. This can allow a user to interact with the mobile device using the secondary display when the main display is off. The secondary display can comprise virtual buttons for many different functions, such as taking pictures or video, zooming in or out, adjusting volume, turning the device off, turning the main display on, changing the information that is displayed on the secondary display, etc. In some embodiments, the secondary display can be used for decorative purposes as well, such as to display aesthetic images or lighting patterns.

A mobile device comprising plural displays can further comprise one or more controllers to determine when to turn each display on or off, and to determine what to display on each display when they are on. These determinations can be based on programmable logic stored in the mobile device. Exemplary factors that can be used to make such determinations can comprise battery power level, type of incoming information (e.g., incoming phone call, text message, email, news alert, etc.), state of proximity detector, state of gyroscopic sensor, state of light sensor, user preferences, and/or other factors.

In some embodiments, the controller can turn off a main display if a proximity sensor, light sensor, and/or gyroscopic sensor indicate that the main display is obscured, such as if the main display is positioned against a user's ear during a phone call or if the main display is face down on a table. In such situations, the controller may or may not turn the secondary display on. For example, if the device is being used for a phone call, all the display can be turned off, and if the main display is face down on a table, secondary displays on the sides, ends, or rear of the device can be turned on to display information.

In some embodiments, the secondary display can be turned off when a user interact with or uses a main display. In some embodiments, the secondary display can ignore or reject touches when the user is interacting with the main display, such as when a user is cradling a mobile phone and touching the secondary displays with one hand while interacting with the main display with the other hand. For another example, the secondary display can be turned off and/or can ignore touches when the device senses that three or more fingers are touching that secondary device at the same time, which can indicate that the those fingers are being used to hold the device instead of interacting with the secondary display. For another example, the secondary display can be turned off and/or can ignore touches when the device senses that two or more sides of the device are being touched at the same time, which can also indicate that the those plural touches are being used to hold the device instead of interacting with the secondary display. For yet another example, the secondary display can be turned off and/or can ignore touches when the device senses that the main display is facing up and the device is being touched on more than one side or end of the device. For still another example, the secondary display can be turned off and/or can ignore touches when the device senses that more than a predetermined percentage of the secondary display is covered, such as more than 50% or more than 70%.

In some embodiments, if the device senses that the device is in a vertical or non-horizontal position and being held on two or more sides, the controller can switch the secondary displays to a camera mode and display features like a trigger button, zoom buttons, etc., on the secondary display.

In some embodiments, the secondary display can only turn on if the main display is parallel to the ground, or horizontal. In some of these embodiments, the secondary display is only turned on of the main display is facing downwardly or against a surface.

In some embodiments, the controller can turn on the currently off main display when a user touches a secondary display that is currently displaying snacking information. For example, if a user touches an indicator of a new email on the secondary display, the full text of the email can appear on the main display.

In some embodiments, if the mobile device is currently in a speaker phone mode during a call, if a user makes a swipe motion along a secondary display, the mobile device can adjust the volume of the call and/or can turn on the main display to provide additional in-call options.

In some embodiments, the secondary display can be controlled by a separate controller and/or a separate graphics processor than the main display. The controller and/or graphics processor for the secondary display can significantly more energy efficient than that controller and/or graphics processor for the main display. In such embodiments, when the main display is off and the secondary display is on to display information, significant power savings can be achieved compared to if the main display was used to display the same information.

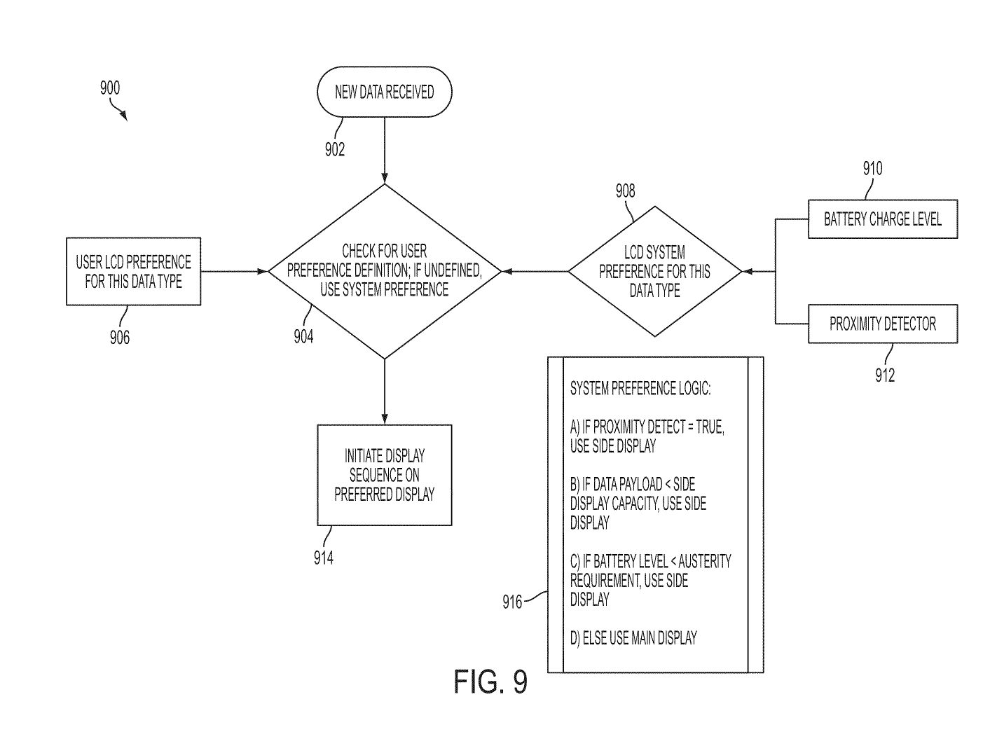

FIG. 9 is a flow chart illustrating an exemplary logic flow for display use selection. At 902, data or information is received from one or more sensors and/or from incoming information, or is otherwise identified. At 904, a check can be made for user selected preference definitions and/or system preferences, based on the received data from 902. If a user preference is undefined, a system preference can be used. At 906, a user display preference can be selected or determined for the type of data received at 902 and this preference can be used in the determination at 904. At 908, a display system preference can be determined for the type of data received at 902 and this preference can also be used in the determination at 904. The determination at 908 can be based on inputs such as the battery charge level 910 and the status of the proximity detector 912. At 904, a determination can be made as to which of the main and secondary displays should be on or off, based on the inputs from 902, 904, and 906. The display determination from 904 can be used at 914 to initiate a display sequence on a preferred display. An exemplary system preference logic is shown at 916. In the exemplary system preference logic, if the proximity detector indicates the main display is proximate a surface, a secondary side display can be turned on or used. If the data payload, or volume of data to be displayed, is less than equal to the capacity of the secondary display, then the secondary display can be used to display that information. If the battery charge level is less than a predetermined austerity threshold, then the secondary display can be used in favor of the main display to conserve energy. Otherwise, the main display can be used instead of the secondary display. 916 is a simplified example of display preference logic, and the logic can be more complex and nuanced in other examples.

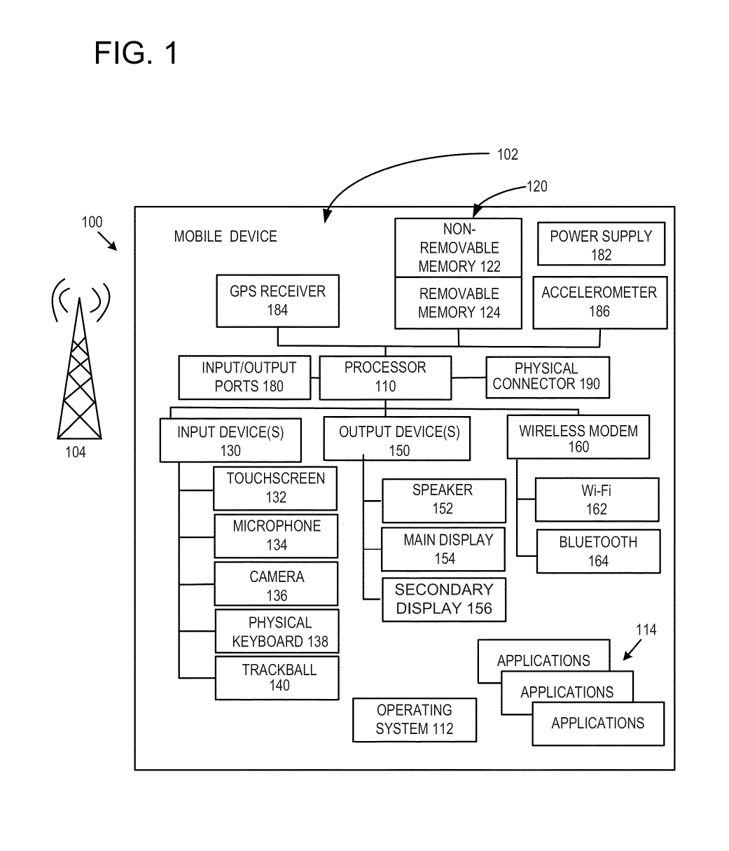

FIG.1 is a system diagram depicting an exemplary mobile device 100 including a variety of optional hardware and software components, shown generally at 102. Any components 102 in the mobile device can communicate with any other component, although not all connections are shown, for ease of illustration. The mobile device can be any of a variety of computing devices (e.g., cell phone, smartphone, handheld computer, Personal Digital Assistant (PDA), etc.) and can allow wireless two-way communications with one or more mobile communications networks 104, such as a cellular or satellite network.

The illustrated mobile device 100 can include a controller or processor 110 (e.g., signal processor, microprocessor, ASIC, or other control and processing logic circuitry) for performing such tasks as signal coding, data processing, input/output processing, power control, and/or other functions. An operating system 112 can control the allocation and usage of the components 102 and support for one or more application programs 114. The application programs can include common mobile computing applications (e.g., email applications, calendars, contact managers, web browsers, messaging applications), or any other computing application. Functionality 113 for accessing an application store can also be used for acquiring and updating applications 114.

The illustrated mobile device 100 can include memory 120. Memory 120 can include non-removable memory 122 and/or removable memory 124. The non-removable memory 122 can include RAM, ROM, flash memory, a hard disk, or other well-known memory storage technologies. The removable memory 124 can include flash memory or a Subscriber Identity Module (SIM) card, which is well known in GSM communication systems, or other well-known memory storage technologies, such as “smart cards.” The memory 120 can be used for storing data and/or code for running the operating system 112 and the applications 114. Example data can include web pages, text, images, sound files, video data, or other data sets to be sent to and/or received from one or more network servers or other devices via one or more wired or wireless networks. The memory 120 can be used to store a subscriber identifier, such as an International Mobile Subscriber Identity (IMSI), and an equipment identifier, such as an International Mobile Equipment Identifier (IMEI). Such identifiers can be transmitted to a network server to identify users and equipment.

The mobile device 100 can support one or more input devices 130, such as a touchscreen 132, microphone 134, camera 136, physical keyboard 138 and/or trackball 140 and one or more output devices 150, such as a speaker 152, a main display 154, and/or one or more secondary displays 156. Other possible output devices (not shown) can include piezoelectric or other haptic output devices. Some devices can serve more than one input/output function. For example, touchscreen 132 and displays 154, 156 can be combined in a single input/output device. The input devices 130 can include a Natural User Interface (NUI). An NUI is any interface technology that enables a user to interact with a device in a “natural” manner, free from artificial constraints imposed by input devices such as mice, keyboards, remote controls, and the like. Examples of NUI methods include those relying on speech recognition, touch and stylus recognition, gesture recognition both on screen and adjacent to the screen, air gestures, head and eye tracking, voice and speech, vision, touch, gestures, and machine intelligence. Other examples of a NUI include motion gesture detection using accelerometers/gyroscopes, facial recognition, 3D displays, head, eye, and gaze tracking, immersive augmented reality and virtual reality systems, all of which provide a more natural interface, as well as technologies for sensing brain activity using electric field sensing electrodes (EEG and related methods). Thus, in one specific example, the operating system 112 or applications 114 can comprise speech-recognition software as part of a voice user interface that allows a user to operate the device 100 via voice commands. Further, the device 100 can comprise input devices and software that allows for user interaction via a user's spatial gestures, such as detecting and interpreting gestures to provide input to a gaming application.

A wireless modem 160 can be coupled to an antenna (not shown) and can support two-way communications between the processor 110 and external devices, as is well understood in the art. The modem 160 is shown generically and can include a cellular modem for communicating with the mobile communication network 104 and/or other radio-based modems (e.g., Bluetooth 164 or Wi-Fi 162). The wireless modem 160 is typically configured for communication with one or more cellular networks, such as a GSM network for data and voice communications within a single cellular network, between cellular networks, or between the mobile device and a public switched telephone network (PSTN).

The mobile device can further include at least one input/output port 180, a power supply 182, a satellite navigation system receiver 184, such as a Global Positioning System (GPS) receiver, an accelerometer 186, and/or a physical connector 190, which can be a USB port, IEEE 1394 (FireWire) port, and/or RS-232 port. The illustrated components 102 are not required or all-inclusive, as any components can be deleted and other components can be added.

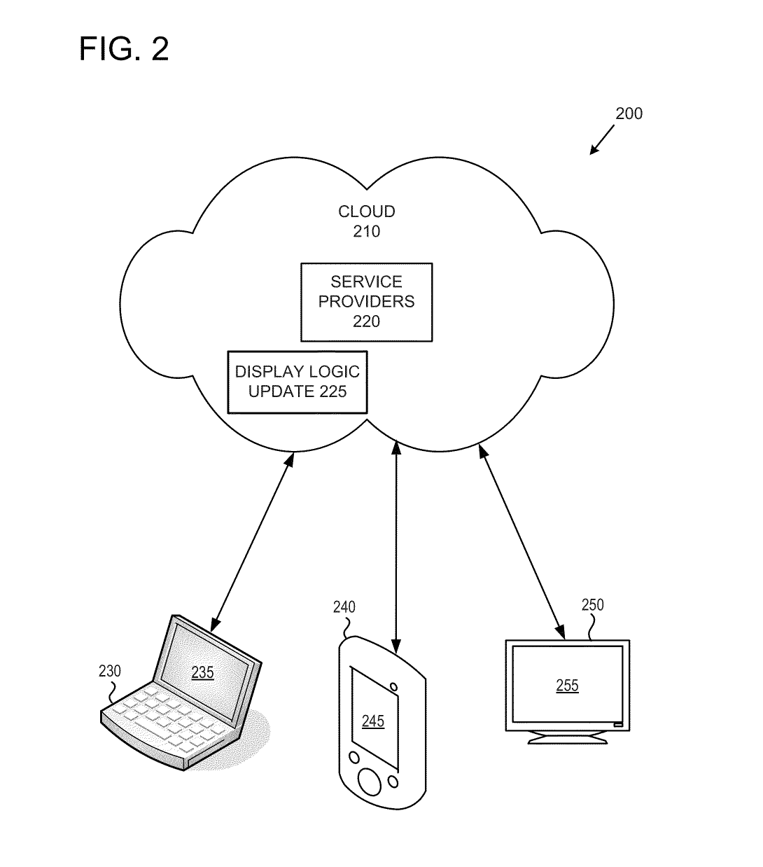

FIG. 2 illustrates a generalized example of a suitable implementation environment 200 in which described embodiments, techniques, and technologies may be implemented.

In example environment 200, various types of services (e.g., computing services) are provided by a cloud 210. For example, the cloud 210 can comprise a collection of computing devices, which may be located centrally or distributed, that provide cloud-based services to various types of users and devices connected via a network such as the Internet. The implementation environment 200 can be used in different ways to accomplish computing tasks. For example, some tasks (e.g., processing user input and presenting a user interface) can be performed on local computing devices (e.g., connected devices 230, 240, 250) while other tasks (e.g., storage of data to be used in subsequent processing) can be performed in the cloud 210.

In example environment 200, the cloud 210 provides services for connected devices 230, 240, 250 with a variety of screen capabilities. Connected device 230 represents a device with a computer screen 235 (e.g., a mid-size screen). For example, connected device 230 could be a personal computer such as desktop computer, laptop, notebook, netbook, or the like. Connected device 240 represents a device with a mobile device screen 245 (e.g., a small size screen). For example, connected device 240 could be a mobile phone, smart phone, personal digital assistant, tablet computer, or the like. Connected device 250 represents a device with a large screen 255. For example, connected device 250 could be a television screen (e.g., a smart television) or another device connected to a television (e.g., a set-top box or gaming console) or the like. One or more of the connected devices 230, 240, 250 can include touchscreen capabilities. Touchscreens can accept input in different ways. For example, capacitive touchscreens detect touch input when an object (e.g., a fingertip or stylus) distorts or interrupts an electrical current running across the surface. As another example, touchscreens can use optical sensors to detect touch input when beams from the optical sensors are interrupted. Physical contact with the surface of the screen is not necessary for input to be detected by some touchscreens. Devices without screen capabilities also can be used in example environment 200. For example, the cloud 210 can provide services for one or more computers (e.g., server computers) without displays.

Services can be provided by the cloud 210 through service providers 220, or through other providers of online services (not depicted). For example, cloud services can be customized to the screen size, display capability, and/or touchscreen capability of a particular connected device (e.g., connected devices 230, 240, 250). In some embodiments, connected devices having more than one display can communicate with the cloud 210 to receive updates 225 and/or changes to their display logic, such as the change way in which the different screens are used to perform various functions.

In example environment 200, the cloud 210 provides the technologies and solutions described herein to the various connected devices 230, 240, 250 using, at least in part, the service providers 220. For example, the service providers 220 can provide a centralized solution for various cloud-based services. The service providers 220 can manage service subscriptions for users and/or devices (e.g., for the connected devices 230, 240, 250 and/or their respective users).

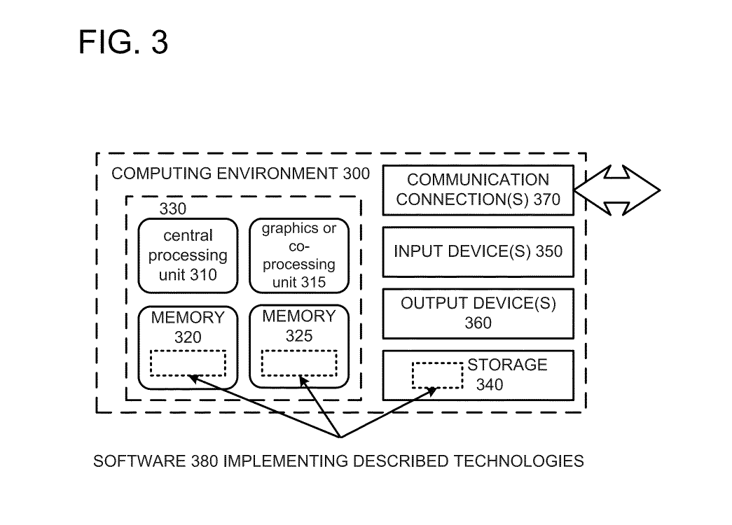

FIG. 3 depicts a generalized example of a suitable computing environment 300 in which the described innovations may be implemented. The computing environment 300 is not intended to suggest any limitation as to scope of use or functionality, as the innovations may be implemented in diverse general-purpose or special-purpose computing systems. For example, the computing environment 300 can be any of a variety of computing devices (e.g., desktop computer, laptop computer, server computer, tablet computer, media player, gaming system, mobile device, etc.)

With reference to FIG. 3, the computing environment 300 includes one or more processing units 310, 315 and memory 320, 325. In FIG. 3, this basic configuration 330 is included within a dashed line. The processing units 310, 315 execute computer-executable instructions. A processing unit can be a general-purpose central processing unit (CPU), a graphics processing unit (GPU), a processor in an application-specific integrated circuit (ASIC), or any other type of processor. In a multi-processing system, multiple processing units execute computer-executable instructions to increase processing power. For example, FIG. 3 shows a central processing unit 310 as well as a graphics processing unit or co-processing unit 315. The tangible memory 320, 325 may be volatile memory (e.g., registers, cache, RAM), non-volatile memory (e.g., ROM, EEPROM, flash memory, etc.), or some combination of the two, accessible by the processing unit(s). The memory 320, 325 stores software 380 implementing one or more innovations described herein, in the form of computer-executable instructions suitable for execution by the processing unit(s).

A computing system may have additional features. For example, the computing environment 300 includes storage 340, one or more input devices 350, one or more output devices 360, and one or more communication connections 370. An interconnection mechanism (not shown) such as a bus, controller, or network interconnects the components of the computing environment 300. Typically, operating system software (not shown) provides an operating environment for other software executing in the computing environment 300, and coordinates activities of the components of the computing environment 300.

The tangible storage 340 may be removable or non-removable, and includes magnetic disks, magnetic tapes or cassettes, CD-ROMs, DVDs, or any other storage device which can be used to store information and which can be accessed within the computing environment 300. The storage 340 stores instructions for the software 380 implementing one or more innovations described herein.

The input device(s) 350 may be a touch input device such as a touchscreen, keyboard, mouse, pen, or trackball, a voice input device, a scanning device, or another device that provides input to the computing environment 300. For video encoding, the input device(s) 350 may be a camera, video card, TV tuner card, or similar device that accepts video input in analog or digital form, or a CD-ROM or CD-RW that reads video samples into the computing environment 300. The output device(s) 360 may be one or more displays, printer, speaker, CD-writer, or another device that provides output from the computing environment 300.

The communication connection(s) 370 enable communication over a communication medium to another computing entity. The communication medium conveys information such as computer-executable instructions, audio or video input or output, or other data in a modulated data signal. A modulated data signal is a signal that has one or more of its characteristics set or changed in such a manner as to encode information in the signal. By way of example, and not limitation, communication media can use an electrical, optical, RF, or other carrier.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed methods can be used in conjunction with other methods.

Any of the disclosed methods can be implemented as computer-executable instructions stored on one or more computer-readable storage media (e.g., one or more optical media discs, volatile memory components (such as DRAM or SRAM), or nonvolatile memory components (such as flash memory or hard drives)) and executed on a computer (e.g., any commercially available computer, including smart phones, tablets, or other mobile devices that include computing hardware). As should be readily understood, the term computer-readable storage media does not include communication connections, such as modulated data signals. Any of the computer-executable instructions for implementing the disclosed techniques as well as any data created and used during implementation of the disclosed embodiments can be stored on one or more computer-readable media (which excludes propagated signals). The computer-executable instructions can be part of, for example, a dedicated software application or a software application that is accessed or downloaded via a web browser or other software application (such as a remote computing application). Such software can be executed, for example, on a single local computer (e.g., any suitable commercially available computer) or in a network environment (e.g., via the Internet, a wide-area network, a local-area network, a client-server network (such as a cloud computing network), or other such network) using one or more network computers.

For clarity, only certain selected aspects of the software-based implementations are described. Other details that are well known in the art are omitted. For example, it should be understood that the disclosed technology is not limited to any specific computer language or program. For instance, the disclosed technology can be implemented by software written in C++, Java, Perl, JavaScript, Adobe Flash, or any other suitable programming language. Likewise, the disclosed technology is not limited to any particular computer or type of hardware. Certain details of suitable computers and hardware are well known and need not be set forth in detail in this disclosure.

It should also be well understood that any functionality described herein can be performed, at least in part, by one or more hardware logic components, instead of software. For example, and without limitation, illustrative types of hardware logic components that can be used include Field-programmable Gate Arrays (FPGAs), Program-specific Integrated Circuits (ASICs), Program-specific Standard Products (ASSPs), System-on-a-chip systems (SOCs), Complex Programmable Logic Devices (CPLDs), etc.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, software applications, cable (including fiber optic cable), magnetic communications, electromagnetic communications (including RF, microwave, and infrared communications), electronic communications, or other such communication means.

The disclosed methods, apparatus, and systems should not be construed as limiting in any way. Instead, the present disclosure is directed toward all novel and nonobvious features and aspects of the various disclosed embodiments, alone and in various combinations and subcombinations with one another. The disclosed methods, apparatus, and systems are not limited to any specific aspect or feature or combination thereof, nor do the disclosed embodiments require that any one or more specific advantages be present or problems be solved.

In view of the many possible embodiments to which the principles disclosed herein may be applied, it should be recognized that the illustrated embodiments are only preferred examples and should not be taken as limiting the scope of the disclosure. Rather, the scope of the disclosure is defined by the following claims. We therefore claim all that comes within the scope of these claims.

We claim:

1. A mobile computing device comprising:
a monolithic body comprising a front side, a rear side, and four lateral sides extending between the front side and the rear side;
a main electronic display on the front side; and
a secondary electronic display on the front side or on one of the lateral sides.

2. The device of claim 1, wherein the main display and the secondary display comprise two discrete display devices.

3. The device of claim 1, wherein the main display and the secondary display are both touch-sensitive input devices as well as visual display devices.

4. The device of claim 1, wherein the main display and the secondary display are configured to be turned on and off independently of each other.

5. The device of claim 1, wherein the main display and the secondary display are touching along a common edge.

6. The device of claim 1, wherein the main display is disposed in a plane that is non-parallel with a plane in which the secondary display is disposed.

7. The device of claim 1, wherein an edge of the secondary display is coupled to an edge of the main display with a compliant gasket.

8. The device of claim 1, wherein the main display comprises a beveled edge that mates with a beveled edge of the secondary display.

9. The device of claim 6, further comprising a one-piece, at least partially transparent cover layer that covers both the main display and the secondary display.

10. The device of claim 9, wherein the cover layer extends around one or more edges of the mobile device and along at least two sides of the mobile device.

11. The device of claim 1, further comprising at least a second secondary display.

12. The device of claim 11, wherein two secondary displays are disposed on opposite sides of the main display and configured to display information sweeping around three sides of the device in continuous motion.

13. The device of claim 1, wherein the secondary display is on a lateral side of the body and is disposed in a plane that forms a non-right angle relative to a plane of the main display.

14. The device of claim 9, wherein a portion of the cover layer that covers the secondary display comprises a convex outer surface.

15. The device of claim 4, further comprising at least one display controller configured to control whether the main display is powered on or off, control whether the secondary display is powered on or off, and control what information is displayed when either screen is powered on, based on input data received from one or more sensors, a battery charge level input, and characteristics of external wireless data received by the device that is to be displayed.

16. A method of controlling a main display and a secondary display of a mobile computing device, the method comprising:
identifying information to be displayed;
determining whether to display the identified information on the main display or on the secondary display based on an input from a proximity detector, a battery charge level, and characteristics of the identified information; and
displaying the identified information on either the main display or the secondary display.

17. The method of claim 16, wherein the determining whether to display the identified information on the main display or on the secondary display comprises determining if the main display is adjacent to another surface using the proximity detector, and if so, then displaying the identified information on the secondary display.

18. The method of claim 16, wherein the determining whether to display the identified information on the main display or on the secondary display comprises determining if a size of the identified information is less than a size capacity of the secondary display, and if so, then displaying the identified information on the secondary display.

19. The method of claim 16, wherein the determining whether to display the identified information on the main display or on the secondary display comprises determining if the battery charge level is less than a predetermined austerity threshold, and if so, then displaying the identified information on the secondary display.

20. A mobile computing device comprising:
a body having a non-hinged, bar-type form factor and comprising a front side, a rear side, and four lateral sides;
a main display on the front side of the body; and
a secondary display on one of the four lateral sides of the body;
wherein an outer surface of the secondary display is in a plane that is not parallel with a plane of an outer surface of the main display;
wherein an edge of the secondary display is adjacent to an edge of the main display, and the adjacent edges are positioned in contact with each other, are joined together with an adhesive, or are joined together with a compliant gasket;
wherein the main display and the secondary display can be controlled independently of each other based on predetermined display preference logic; and
the device further comprises a one-piece, at least partially transparent cover layer that covers and protects both the main display and the secondary display and extends around the adjacent edges of the main display and the secondary display.
